(19) United States
(12) Patent Application Publication
(10) Pub. No.: US 2024/0124500 A1
(43) Pub. Date: Apr. 18, 2024

(54) CYCLIC AZASTANNANE AND CYCLIC OXOSTANNANE COMPOUNDS AND METHODS FOR PREPARATION THEREOF

(71) Applicants: Gelest, Inc., Morrisville, PA (US); Mitsubishi Chemical Corporation, Tokyo (JP)

(72) Inventor: Li YANG, Belle Mead, NJ (US)

(21) Appl. No.: 18/373,404

(22) Filed: Sep. 27, 2023

Related U.S. Application Data
(60) Provisional application No. 63/412,959, filed on Oct. 4, 2022.

(51) Int. Cl. C07F 7/22

(52) U.S. Cl. CPC C07F 7/2288

(57) ABSTRACT

Cyclic azastannanes and cyclic oxostannanes having formulas (I) and (II) where X is an alkoxy or dialkylamino group are a new class of cyclic compounds. These compounds have desirably high vapor pressure and high purity (containing low levels of polyalkyl contaminants after purification), and have particular interest for EUV photoresist applications. Methods for preparing these compounds are described.

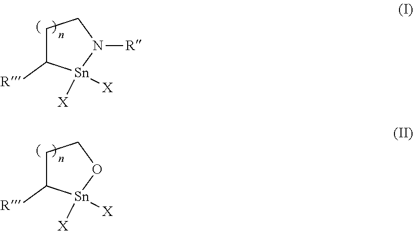

### CROSS-REFERENCE TO RELATED APPLICATIONS

This application claims priority to US Provisional Application No. 63/412,959, filed Oct. 4, 2022, the disclosures of which is herein incorporated by reference in its entirety.

### BACKGROUND OF THE INVENTION

As semiconductor fabrication continues to advance, feature sizes continue to shrink, driving the need for new processing methods. Certain organotin compounds have been shown to be useful in the deposition of tin oxide hydroxide coatings in applications such as extreme ultraviolet (EUV) lithography techniques. For example, alkyl tin compounds provide radiation sensitive Sn—C bonds that can be used to pattern structures lithographically.

Materials used in microelectronic fabrication are required to be extremely pure with tight limits placed on organic contamination (e.g., reaction by-products), metallic contamination, and particulate contamination. Purity requirements are stringent in general, and particularly for lithography applications because the chemical is in contact with the semiconductor substrates and the organometallic impurities in compounds such as (iPr)Sn(NMe₂)₃ can affect the properties of the resultant film. Exact targets for purities are determined by a variety of factors, including performance metrics, but typical minimum purity targets are 3N+. Residual metals present in the chemicals can be deposited onto the semiconductor substrate and degrade the electrical performance of the device being fabricated. Typical specification for metals are less than 10 ppb for individual metals and total metal not to exceed —100 ppb.

Cyclic azasilanes are known to be useful for the functionalization of microelectronic and optoelectronic devices, as well as in ASD applications. Cyclic azastannanes and cyclic oxostannanes, particularly those having high purity, have the potential to be useful in these microelectronic applications as well. However, the ability to prepare and isolate cyclic tin compounds having desired high purity levels has not previously been reported.

### BRIEF SUMMARY OF THE INVENTION

A cyclic azastannane according to an embodiment of the disclosure has formula (I):

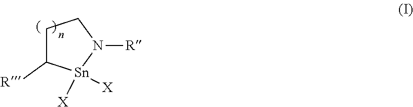

wherein X is OR or NR′₂, n is an integer of 1 to 3, R is a primary, secondary, or tertiary alkyl group having 1 to about 5 carbon atoms or a substituted or unsubstituted aryl group having about 6 to about 10 carbon atoms, R′ is a primary alkyl group having 1 to about 2 carbon atoms, R″ is hydrogen, a substituted or unsubstituted primary, secondary, or tertiary, saturated or unsaturated, linear, branched, or cyclic alkyl group having 1 to about 20 carbon atoms, a substituted or unsubstituted, branched or linear aralkyl group having about 7 to about 10 carbon atoms, or a substituted or unsubstituted aryl group having about 6 to about 10 carbon atoms, and R′″ is hydrogen, a substituted or unsubstituted primary, secondary, or tertiary, saturated or unsaturated, linear, branched, or cyclic alkyl group having 1 to about 20 carbon atoms, a substituted or unsubstituted, branched or linear aralkyl group having about 7 to about 10 carbon atoms, or a substituted or unsubstituted aryl group having about 6 to about 10 carbon atoms.

A cyclic oxostannane according to an embodiment of the disclosure has formula (II):

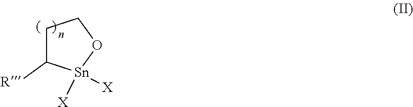

wherein X is OR or NR′₂, n is an integer of 1 to 3, R is a primary, secondary, or tertiary alkyl group having 1 to about 5 carbon atoms or a substituted or unsubstituted aryl group having about 6 to about 10 carbon atoms, R′ is a primary alkyl group having 1 to about 2 carbon atoms, and R′″ is hydrogen, a substituted or unsubstituted primary, secondary, or tertiary, saturated or unsaturated, linear, branched, or cyclic alkyl group having 1 to about 20 carbon atoms, a substituted or unsubstituted, branched or linear aralkyl group having about 7 to about 10 carbon atoms, or a substituted or unsubstituted aryl group having about 6 to about 10 carbon atoms.

In a further embodiment, aspects of the disclosure relate to a method for producing a cyclic azastannane having formula (I):

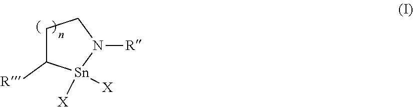

wherein X is OR, n is an integer of 1 to 3, R is a primary, secondary, or tertiary alkyl group having 1 to about 5 carbon atoms or a substituted or unsubstituted aryl group having about 6 to about 10 carbon atoms, R″ is hydrogen, a substituted or unsubstituted primary, secondary, or tertiary, saturated or unsaturated, linear, branched, or cyclic alkyl group having 1 to about 20 carbon atoms, a substituted or unsubstituted, branched or linear aralkyl group having about 7 to about 10 carbon atoms, or a substituted or unsubstituted aryl group having about 6 to about 10 carbon atoms, and R′″ is hydrogen, a substituted or unsubstituted primary, secondary, or tertiary, saturated or unsaturated, linear, branched, or cyclic alkyl group having 1 to about 20 carbon atoms, a substituted or unsubstituted, branched or linear aralkyl group having about 7 to about 10 carbon atoms, or a substituted or unsubstituted aryl group having about 6 to about 10 carbon atoms, the method comprising reacting an aminoalkyltrialkoxystannane or an aminoalkyltriaryloxystannane with a compound selected from the group consisting of HMDZ, an ammonium salt, sulfuric acid, a phosphonium salt, and an organolithium compound.

In a further embodiment, aspects of the disclosure relate to a method for producing a cyclic azastannane having formula (I):

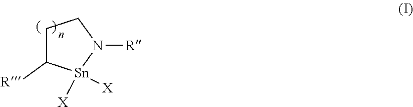

wherein X is NR′₂, n is an integer of 1 to 3, R′ is a primary alkyl group having 1 to about 2 carbon atoms, R″ is a substituted or unsubstituted primary, secondary, or tertiary, saturated or unsaturated, linear, branched, or cyclic alkyl group having 1 to about 20 carbon atoms, a substituted or unsubstituted, branched or linear aralkyl group having about 7 to about 10 carbon atoms, or a substituted or unsubstituted aryl group having about 6 to about 10 carbon atoms, and R′″ is hydrogen, a substituted or unsubstituted primary, secondary, or tertiary, saturated or unsaturated, linear, branched, or cyclic alkyl group having 1 to about 20 carbon atoms, a substituted or unsubstituted, branched or linear aralkyl group having about 7 to about 10 carbon atoms, or a substituted or unsubstituted aryl group having about 6 to about 10 carbon atoms, the method comprising heating an aminoalkyltrialkylaminostannane to effect cyclization.

In a further embodiment, aspects of the disclosure relate to a method for producing a cyclic oxostannane having formula (II):

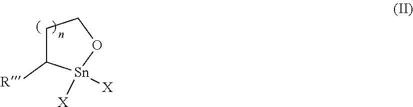

wherein X is OR, n is an integer of 1 to 3, R is a primary, secondary, or tertiary alkyl group having 1 to about 5 carbon atoms or a substituted or unsubstituted aryl group having about 6 to about 10 carbon atoms and R′″ is hydrogen, a substituted or unsubstituted primary, secondary, or tertiary, saturated or unsaturated, linear, branched, or cyclic alkyl group having 1 to about 20 carbon atoms, a substituted or unsubstituted, branched or linear aralkyl group having about 7 to about 10 carbon atoms, or a substituted or unsubstituted aryl group having about 6 to about 10 carbon atoms, the method comprising reacting a trichlorostannyl alcohol with a metal alkoxide to produce a trialkoxystannyl alcohol, and heating to effect cyclization.

In a further embodiment, aspects of the disclosure relate to a method for producing a cyclic oxostannane having formula (II):

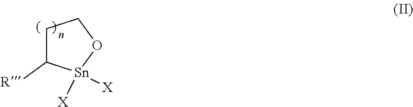

wherein X is NR′₂, n is an integer of 1 to 3, R′ is a primary alkyl group having 1 to about 2 carbon atoms, and R′″ is hydrogen, a substituted or unsubstituted primary, secondary, or tertiary, saturated or unsaturated, linear, branched, or cyclic alkyl group having 1 to about 20 carbon atoms, a substituted or unsubstituted, branched or linear aralkyl group having about 7 to about 10 carbon atoms, or a substituted or unsubstituted aryl group having about 6 to about 10 carbon atoms, the method comprising reacting (dialkylamino)trimethylsilane with a cyclic oxostannane having formula (II) wherein X is OR and R is a primary, secondary, or tertiary alkyl group having 1 to about 5 carbon atoms.

### DETAILED DESCRIPTION OF THE INVENTION

Aspects of the disclosure relate to a new class of cyclic compounds which may be referred to as hydridostannapyrroles and hydridostannafurans, azastannacyclopentanes and oxostannacyclopentanes, or cyclic azastannanes and cyclic oxostannanes. These compounds have desirably high vapor pressure, high water reactivity, and high purity (containing low levels of polyalkyl contaminants after purification). Such compounds contain amide or alkoxy substituents on the tin atom. The cyclic azastannanes and cyclic oxostannanes described herein avoid contamination with polyalkyl tin compounds, tetraalkoxides, and tetraamides after purification.

In some embodiments, the cyclic azastannanes and cyclic oxostannanes are volatile and have particular interest for EUV photoresist applications. For the purposes of this disclosure, a volatile compound is one with sufficient vapor pressure to be transported by a carrier gas such as argon and/or which has the intrinsic ability to diffuse in reaction chambers to a substrate.

The cyclic azastannanes and cyclic oxostannanes according to aspects of the disclosure have the general structures shown in formulas (I) and (II):

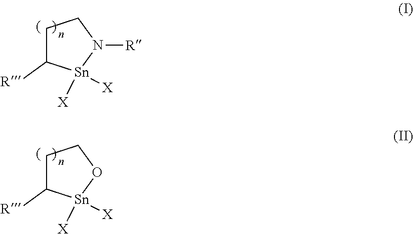

In these five- to seven-membered ring structures, a tin atom is bonded to a carbon atom

and a nitrogen or oxygen in the ring, as well as to two alkoxy or dialkylamino groups, the hydrocarbon portion of the ring may be unsubstituted or substituted.

In formulas (I) and (II), X is OR or NR′₂, n is an integer from 1 to 3, R is a primary, secondary, or tertiary alkyl group having 1 to about 5 carbon atoms (preferably 1 to about 4 carbon atoms) or a substituted or unsubstituted aryl group having about 6 to about 10 carbon atoms, R′ is a primary alkyl group having 1 to about 2 carbon atoms, and R″ is hydrogen, a substituted or unsubstituted, primary, secondary, or tertiary, saturated or unsaturated, linear, branched, or cyclic alkyl group having 1 to about 20 carbon atoms, more preferably about 1 to about 5 carbon atoms, a substituted or unsubstituted, branched or linear aralkyl group having about 7 to about 10 carbon atoms, or a substituted or unsubstituted aryl group having 6 to about 10 carbon atoms. R′″ may be hydrogen, a substituted or unsubstituted primary, secondary, or tertiary, saturated or unsaturated, linear, branched, or cyclic alkyl group having 1 to about 20 carbon atoms (preferably about 1 to about 6 carbon atoms), a substituted or unsubstituted, branched or linear aralkyl group having about 7 to about 10 carbon atoms, or a substituted or unsubstituted aryl group having about 6 to about 10 carbon atoms, For example, R may be a methyl, ethyl, isopropyl, or t-butyl group, preferably an isopropyl or t-butyl group, R′ may be a methyl or ethyl group, and R″ may be hydrogen, a linear or branched alkyl group such as methyl, ethyl, propyl, isopropyl, n-propyl, or t-butyl, an alkenyl, alkynyl, or allyl group, or a phenyl group; presently preferred are methyl, ethyl, and vinyl groups. Examples of R′″ include hydrogen, a linear or branched alkyl group such as methyl, ethyl, propyl, isopropyl, n-propyl, or t-butyl, an alkenyl, alkynyl, or allyl group, or a phenyl group; presently preferred are hydrogen, methyl, ethyl, and vinyl groups.

Some specific examples of cyclic azastannane and cyclic oxostannane compounds according to the disclosure include N,N,N′,N′,1-pentamethyl-1,2-azastannolidine-2,2-diamine; 1-ethyl-N,N,N′,N′-tetramethyl-1,2-azastannoli dine-2,2-di amine; N,N,N′,N′-tetramethyl-l-vinyl-1,2-azastannoli dine-2,2-di amine; 2,2-di-tert-butoxy-l-methyl-1,2-azastannoli dine; 2,2-di-tert-butoxy-1-ethyl-1,2-azastannoli dine; 2,2-di-tert-butoxy-l-vinyl-1,2-azastannoli dine; 2,2-dimethoxy-1,2-oxastannolane; 2,2-di-tert-butoxy-1,2-oxastannolane; and 2,2-di-tert-butoxy-3-methyl-1,2-oxastannolane, having the structures shown below.

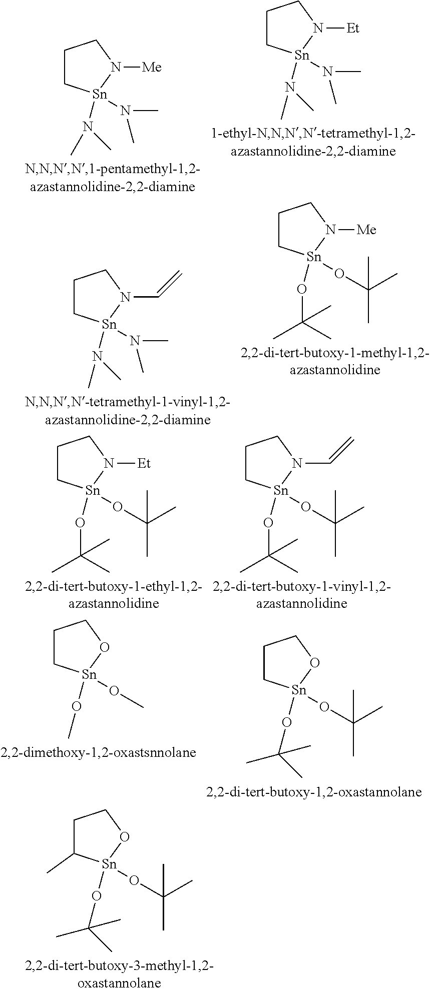

After purification, the compounds having formulas (I) and (II) have high purity, such as greater than about 90 mol%, greater than about 95 mol %, greater than about 97 mol %, greater than about 99 mol %, greater than about 99.2 mol %, greater than about 99.5 mol %, greater than about 99.6 mol %, greater than about 99.7 mol %, greater than about 99.8 mol %, or greater than about 99.9 mol %, and contain less than about 1% tetrakis tin compounds. In preferred embodiments, the compounds having formula (I) further contain less than about 1 mol % diazastannane compounds, less than about 1 mol % tetraalkoxide compounds, and/or less than about 1 mol % tetraamide compounds, such as less than about 0.8 mol %, less than about 0.5 mol %, less than about 0.3 mol %, less than about 0.2 mol %, or less than about 0.1 mol % of one or more of these impurity compounds. For example, N,N,N′,N′,1-pentamethyl-1,2-azastannolidine-2,2-diamine contains less than 1% 1,6-dimethyl-1,6-diaza-5-stannaspiro[4.4]nonane.

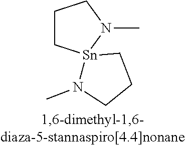

The purities of the compounds described herein may be determined by 119 Sn NMR, which can have detection limits as low as 0.05 mol % when testing the sample without dilution in deuterated solvent.

¹¹⁹Sn NMR spectroscopy is ideally suited to the quantitative analysis of alkyl tin compounds due to its high sensitivity to small structural changes and large spectral range of 6500 ppm (see Davies et al., Eds.; Tin Chemistry: Fundamentals, Frontiers, and Applications; Wiley (2008)). This allows for easy identification and quantification of alkyl tin compounds and their impurities because ¹¹⁹Sn resonances are highly resolved. ¹¹⁹Sn NMR suffers from reduced sensitivity compared to other analytical methods such as GC, HPLC, or ¹H NMR. To improve sensitivity, alkyl tin compounds are analyzed without dilution, and a large number of spectral acquisitions (2000+) are acquired to measure the low levels of impurities described in this work.

The ¹¹⁹Sn NMR data described herein were obtained using a method similar to the relative purity method described in J. Med. Chem. (57, 22, 9220-9231 (2014)). ¹¹⁹Sn NMR spectra were acquired using inverse-gated ¹H decoupling with a 40° pulse, one second relaxation delay, and sufficient scans to achieve the required sensitivity. Samples were prepared without dilution in deuterated solvent. Quantitation was performed by integrating all peaks in the spectrum and setting the total peak area to 100. Each peak in the spectrum represents a distinct tin compound and the area of each peak represents the concentration or purity of that compound in mol %.

### Methods for Preparing Cyclic Azastannanes

A method for preparing cyclic azastannanes having formula (I) and containing alkoxy or aryloxy groups on the ring tin atom (X is OR) preferably comprises reacting an aminoalkyltrialkoxystannane or an aminoalkyltriaryloxystannane with HMDZ (hexamethyldisilazane), an ammonium salt, sulfuric acid, a phosphonium salt, an organolithium compound, or any similar material which is known in the art or to be developed which reacts favorably with an aminoalkyltrialkoxystannane or aminoalkyltriaryloxystannane to form the desired cyclic azastannane, as shown in the examples below. Thus, the only limitation on the cyclic azastannanes which may be produced according to the method of the invention is the ability to synthesize the aminoalkyltrialkoxystannane or aminoalkyltriaryloxystannane precursor.

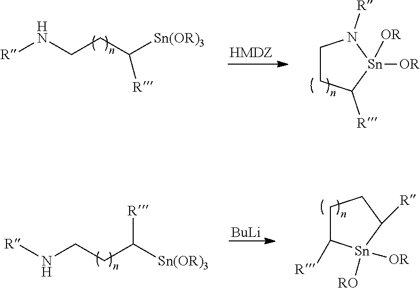

Preferred alkali metal alkyl compounds include organometallic lithium compounds such as the presently preferred butyl lithium. Exemplary phosphonium salts include PyBroP (bromotri(pyrrolidino)phosphonium hexafluorophosphate), BroP (bromotris(dimethylamino)phosphonium hexafluorophosphate), PyBOP ((benzotriazol-1-yloxy)tripyrrolidinophosphonium hexafluorophosphate), and BOP ((benzotriazol-1-yloxy)tris(dimethylamino)phosphonium hexafluorophosphate). Preferred ammonium salts which may be used in accordance with the method described herein include the salts of ammonium with any known anion, such as, without limitation, halide, sulfate, phosphate, and trifluoromethanesulfonate. Particularly preferred ammonium salts include ammonium sulfate and ammonium chloride. Although it is preferred if the ammonium salt is neutral, charged species are also within the scope of the invention.

The reaction is preferably performed in the absence of solvent (neat), but may also be performed in a solution. Preferred solvents include hydrocarbons (such as, but not limited to, hexane, hexanes, heptane, and cyclohexane), aromatics (such as, but not limited to, toluene and xylene), and ethers (such as, but not limited to, THF and Et₂O), and mixtures thereof. Particularly preferred solvents include THF, hydrocarbons, and other aprotic solvents. A preferred concentration of the reactants in solvent, if solvent is employed, is about 5% by weight to about 15% by weight, preferably about 7% by weight to about 12% by weight, more preferably about 10% by weight, but may be determined by routine experimentation. It is preferred that the reaction be initially performed at atmospheric pressure and at a temperature of about room temperature to about 150° C., preferably about 120° C. to about 140° C. After the reaction has proceeded for a period of time, preferably about 30-60 minutes, a vacuum is drawn, such as to about 5 to 15 mm Hg, and any alcohol byproduct formed may be removed from the reaction mixtures, such as by condensation in a cold trap during distillation or other separation technique known in the art or to be developed.

Suitable starting materials which may be used in the method according to the present disclosure include aminoalkyltrialkoxystannanes (for preparing cyclic azastannanes in which R is an alkyl group) which contain, in additional to the amino substituent, three alkoxy substituents on tin. The alkoxy substituent may be an alkoxy group preferably containing from 1 to about 5 carbon atoms, and may be a primary, secondary, or tertiary alkoxy group, such as methoxy, ethoxy, propoxy, isopropoxy, t-butoxy, etc., depending on the alkoxy group which is to be present in the cyclic azastannane. If the desired cyclic azastannane contains an aryl or aralkyl group as R, the starting material is an aminoalkyltriaryloxystannane or an aminoalkyltriaralkoxystannane.

The amino substituent in the aminoalkyltrialkoxystannane or aminoalkyltriaryloxystannane preferably contains at least one N-H group which is preferably located about 3 to about 6 carbon atoms from the tin atom, such as aminopropyl to form a five membered ring; the length of the carbon chain determines the size of the ring in the product. The carbon chain is optionally substituted with a group R′″ in the alpha position relative to the tin if the final compound has an R′″ substituent. The amino substituent may also contain substituted or unsubstituted, saturated or unsaturated, aliphatic hydrocarbon groups or substituted or unsubstituted alkoxy groups, as well as additional substituted or unsubstituted amino groups. For example, the amino substituent may be substituted with an alkyl group, allyl group, or substituted amino group, such as aminoethyl.

Exemplary aminoalkyltrialkoxystannanes include N,N,N′,N′,N″,N″-hexamethyl-1-(3-(methylamino)propyl)stannanetriamine, 1-(3-(ethylamino)propyl)-N,N,N′,N′,N″,N″-hexamethylstannanetriamine, N,N,N′,N′,N″,N″-hexamethyl-1-(3-(vinylamino)propyl)stannanetriamine, N-methyl-3-(tri-tert-butoxystannyl)propan-l-amine, N-ethyl-3-(tri-tert-butoxystannyl)propan-l-amine, and 3-(tri-tert-butoxystannyl)-N-vinylpropan-l-amine.

The aminoalkyltrialkoxystannane starting material may be commercially obtained or prepared, such as by employing the following reaction sequences.

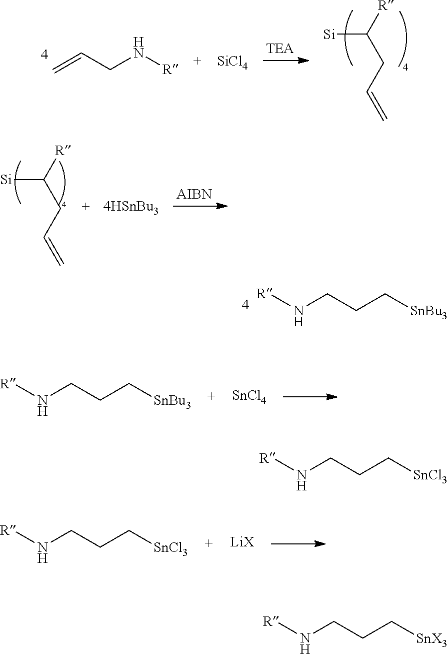

In the above reaction with the aminoalkyltrichlorostannane, X is an alkoxide group, such as methoxide, isopropoxide, or t-butoxide, and is the OR group in the final compound.

Alternatively, the aminoalkyltributyltin compound employed in the third step above may be prepared as follows:

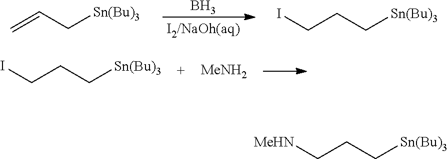

In an analogous fashion, according to another method of the disclosure, cyclic azastannanes having formula (1) containing NR₂ substituents on the ring tin atom may be prepared by heating aminoalkyl tin triamide compounds to effect the cyclization by self-molecular transamination, as shown below.

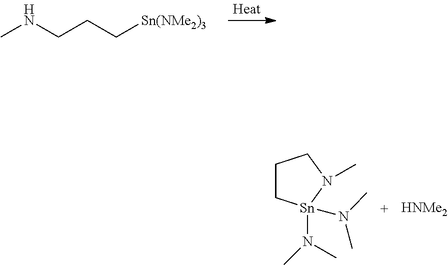

Transamination reactions are versatile process which can occur under mild conditions. While the reactions are reversible, they are usually driven by removing/distilling off the more volatile amine. The reaction temperature range is preferably about 25° C. to about 80° C., depending on the amine by-product boiling point and its solubility in solution. The more preferred operating temperature is about 45° C. to about 65° C., typically achieved by gently refluxing the reaction solvent. In other embodiments, however, the reaction is preferably performed at room temperature. If the temperature is too low, the reaction rate will be too slow, whereas if the temperature is too high, byproducts will be produced.

Preferably, the method is performed in an appropriate solvent. Preferred solvents include hydrocarbons (such as, but not limited to, hexane, hexanes, heptane, and cyclohexane), aromatics (such as, but not limited to, toluene and xylene), and ethers (such as, but not limited to, THF and Et₂O), and mixtures thereof. Particularly presently preferred are hydrocarbons and aromatics as the main component of the solvent for removing remaining metal salts by filtration. Toluene and hexane are presently the most preferred solvents for easy removal of the product under vacuum at low temperature following the reaction.

The concentration of the aminoalkyl tin triamide in solution is preferably up to about 3 M, more preferably up to about 2 M, even more preferably up to about 1 M, or up to about 30 wt %, more preferably up to about 20 wt %, even more preferably up to about 15 wt %, and preferably greater than about 1 wt %, greater than about 2 wt %, greater than about 3 wt %, even more preferably greater than about 5 wt %. It has been found that these dilute concentrations provide effective selective intramolecular reaction. On the other hand, the productivity is lower in dilute concentrations in industrial conditions.

The aminoalkyltrialkylamino tin starting material may be prepared in the same fashion described above, employing lithium dialkylamide rather than lithium alkoxide in the reaction with aminoalkyltin trichloride (aminoalkyltrichlorostannane). Exemplary aminoalkyltrichlorostannanes which may be used to form the aminoalkyltrialkylamino tin starting material include N-methyl-3-(trichlorostannyl)propan-l-amine, N-ethyl-3-(trichlorostannyl)propan-l-amine, and 3-(trichlorostannyl)-N-vinylpropan-1-amine, which have the structures shown below.

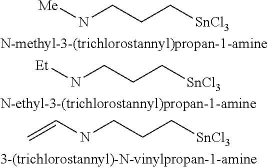

### Methods for Preparing Cyclic Oxostannanes

Cyclic oxostannanes containing alkoxy sub stituents on the ring tin atom may be prepared from trichlorostannyl alcohols (alkyloltrichlorostannanes) by reaction with a metal alkoxide, such as sodium methoxide, to produce the corresponding trialkoxystannyl alcohol, such as 3-(trimethoxystannyl)propan-1-ol, 3-(tri-tert-butoxystannyl)propan-l-ol, or 3-(tri-tert-butoxystannyl)butan-1-ol, followed by heating to effect cyclization. Exemplary alkyloltrichlorostannanes include 3-(trichlorostannyl)propan-l-ol and 3-(trichlorostannyl)butan-l-ol shown below.

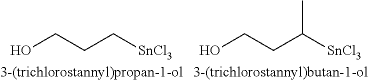

Cyclic oxostannanes containing amino substituents on the ring tin atom may be prepared by reacting a (dialkylamino)trimethylsilane (such as (dimethylamino)trimethylsilane)) with the appropriate cyclic oxostannane having formula (II) wherein X is OR. That is, reaction with (dialkylamino)trimethylsilane converts the alkoxy groups or aryloxy groups on the ring tin atom to amino groups. Appropriate solvents and concentrations for these reactions are as described above. Appropriate temperatures for these reasons may be determined by routine experimentation.

Although silicon and tin are in the same group in the Periodic Table, differences between their reactivities mean that reactions which are effective for producing silane compounds do not work similarly for stannane compounds. For example, aminosilanes can be formed via the direct reaction of chlorosilanes with an amine, whereas amino tin compounds must be formed from lithium amides with tin chloride. In another example, a multi-step synthesis is required to prepare aminoalkyltrichloro tin compounds, whereas the silicon analogs can be simply prepared via hydrosilylation. Further, tin methoxide cannot be prepared by reacting chlorosilane with trimethyl orthoformate and trimethyl orthoacetate, rather, the reaction requires the reaction of tin chloride with MOMe (M=Li, Na, or K). The differences in reactivity between tin and silicon derive in part from the larger size of the tin atom, providing more room for attack from nitrogen and oxygen atoms. Further, tin atoms have empty 5d orbitals which can more easily accept lone pair electrons from oxygen or nitrogen atoms.

All of the method steps for the syntheses of the compounds described herein are preferably performed substantially without light exposure which has detrimental effects on the cyclic azastannane and cyclic oxostannane compounds. Shielding may be accomplished by any method known in the art such as, for example, employing light-shielded containers such as amber glass, metal (SUS) containers, wrapping the container with a light-shielding cover such as cloth, foil or film, using light-shielding coatings, or performing the reactions in a dark room.

The distillations may be performed using a stainless steel column packed with a stainless steel packing material. Alternatively, the distillations may be performed in a light-shielded apparatus comprising glass such as glass equipment, glass-lined equipment, glass-coated equipment, etc. Shielding may be accomplished by any method known in the art such as, for example, employing light-shielded containers such as amber glass, metal (SUS) containers, wrapping the container with a light-shielding cover such as cloth, foil or film, using light-shielding coatings, or performing the distillation in a dark room.

Further aspects of the disclosure relate to a solution containing an organic solvent as described herein and a composition containing organotin compounds having formula (I) and/or formula (II), which may, in some embodiments, be obtained by hydrolysis of a monoorgano tin compound, such as one having formula (I) and/or (II) as described herein. Additional aspects of the disclosure relate to films prepared from or containing a composition containing organotin compounds having formula (I) and/or (II).

The compounds described herein may be used as resist materials after hydrolysis or other reactions such as those known in the art. The compounds described herein may contain a group which is capable of forming an alkyltin oxo-hydroxo-patterning composition which may be hydrolyzed with water or other suitable reagents under suitable conditions to form an alkyltin oxo- hydroxo-patterning composition which may be represented by the formula R^{a}SnO_{(3/2-x/2)}(OH)ₓ (0<x≤3). R^{a} is an organic substitution connected to a Sn atom which generated by hydrolysis of formula (I) or formula (II). Hydrolysis and condensation reactions that may relate to a compound with hydrolytic groups (X) are shown in the following reactions (R means general alkyl groups):

RSnX₃+3H₂O→RSn(OH)₃+3HX

RSn(OH)₃→RSnO(_{1.5-(x/2))}Hx+(x/2) H₂O

Alkyl oxohydroxy tin compounds obtained by hydrolysis using a composition containing RSnX₃ compounds as described above as raw material and the oxohydroxy tin compounds represented by the formula R^{a}SnO_{(3/2-x/2)}(OH)ₓ (0<x≤3) may be used as an EUV resist material.

A method for obtaining oxohydroxy tin compounds (RaSnO) by hydrolyzing a composition containing a RSnX₃ compound may involve, for example, volatilizing a composition containing a RSnX₃ compound under heating or reduced pressure, and reacting the vapor generated by volatilizing the composition on a substrate on which the tin composition is deposited, with water vapor, etc. (a dry method). In this method, a thin film containing the tin compound R′SnO may be formed on the substrate.

Another method may involve reacting a composition containing a R′SnX₃ compound in solution or in a solid state with water, etc., and hydrolyzing it to obtain the oxohydroxy tin compounds (R^{a}SnO). The oxohydroxy tin compounds (R^{a}SnO) may then be used as a coating solution by dissolving it in an organic solvent, for example. The organic solvent is not limited, however in particular, suitable solvents include, for example, aromatic compounds (e.g., xylenes, toluene), ethers (anisole, tetrahydrofuran), esters (propylene glycol monomethyl ether acetate, ethyl acetate, ethyl lactate), alcohols (e.g., 4-methyl-2-propanol, 1-butanol, methanol, isopropyl alcohol, 1-propanol), ketones (e.g., methyl ethyl ketone), halogen solvents (e.g., CH₂Cl₂, CHCl₃) and mixtures thereof. In general, organic solvent selection may be influenced by solubility parameters, volatility, flammability, toxicity, viscosity and potential chemical interactions with other processing materials.

The solution may be applied to a substrate by any coating or printing technique, and a thin film or coating containing oxohydroxy tin compounds (R^{a}SnO) may be formed on the substrate. After the components of the solution are dissolved and combined, the character of the species may change as a result of partial hydration and condensation, especially during the coating process.

The thin film obtained by any of the above methods may be stabilized or partially condensed prior to light irradiation through drying, heating, or other processes. Generally, thin films or coatings have an average thickness of less than about 10 microns, and very thin submicron thin films, e.g., less than about 100 nanometers (nm), even less than about 50 nm or less than about 30 nm, may be desirable for patterning very small features. The resulting thin film or coating may be called a resist because the exposure processes a portion of the composition to be resistant to development/etching.

The thin or coating may be exposed to appropriate radiation, (e.g., extreme ultraviolet, electron beam, deep ultraviolet, or ultraviolet), using a selected pattern or negative portion of the pattern to form a latent image with developer resistant and developer soluble regions. After exposure to the appropriate radiation and prior to development, the thin film or coating may be heated or otherwise reacted to further differentiate the latent image from the non-irradiated areas. The latent image is brought into contact with the developer to form a physical image, i.e., a patterned thin film or coating. The patterned thin film or coating may be further heated to stabilize the remaining patterned coating on the surface. The patterned coating may be used as a physical mask to perform further processing according to the pattern, e.g., etching of the substrate and/or attachment of additional materials. After the patterned resist is used as requested, the remaining patterned coating may be removed at an appropriate point in the processing, but the patterned coating may also be incorporated into the final structure.

The invention will now be described in connection with the following non-limiting prophetic examples.

### Example 1 (Prophetic): Synthesis of N-allyl-N-methyl-1,1,1-tris(methyl-12-azaneyl)silanamine (C)

Compound A is prepared according to the method described in Advanced Synthesis & Catalysis, 363, 1646 (2021), and compound B is prepared according to the method described in Russian Journal of Organic Chemistry, 56, 353 (2020).

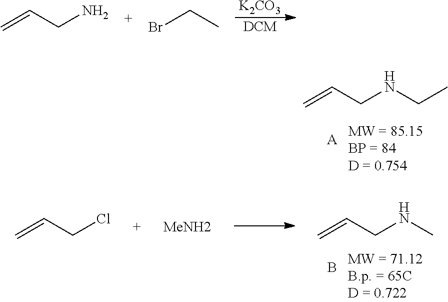

N-allyl-N-methyl-1,1,1-tris(methyl-12-azaneyl)silanamine (C) is then prepared from Compound B as follows, as shown in the following scheme. Under N₂ 355.6 g (5 moles) allylmethylamine (B) 505.95 g (5 moles) TEA (triethylamine), and 1500 mL DCM (dichloromethane) are charged to a 5 L flask. The mixture is cooled to 0° C. and silicon tetrachloride is added dropwise. After addition, the mixture is warmed to room temperature and stirred overnight. Compound C is then isolated and purified by distillation. An analogous reaction may be performed using compound A instead of compound B.

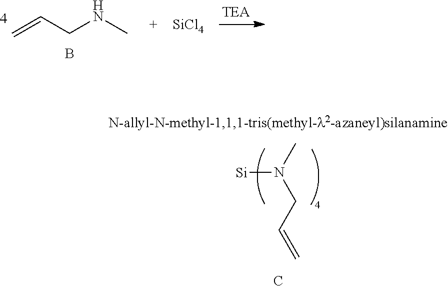

### Example 2 (Prophetic): Synthesis of N-methyl-3-(tributylstannyl)propan-1-amine (D)

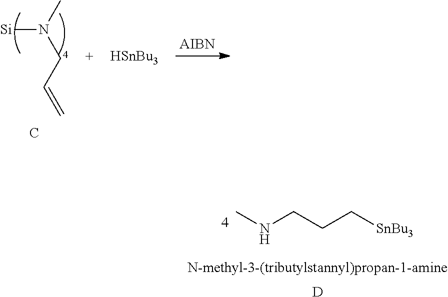

Following the method of J. Org. Chem., 67(25), 8906 (2002), N-methyl-3-(tributylstannyl)propan-1-amine (D) is prepared according to the scheme above as follows. Under N₂, 36.42 g (0.2 mmol) of C, 1979 g (6.8 mmol) of Bu₃SnH, 2000 mL of toluene and 98.95 mg (5 wt % of Bu₃SnH) of ARM are charged into a 5 L flask. The mixture is refluxed for 50 hr. Pure compound D is then obtained by distillation.

### Example 3 (Prophetic): Synthesis of N-methyl-3-(trichlorostannyl)propan-1-amine (E)

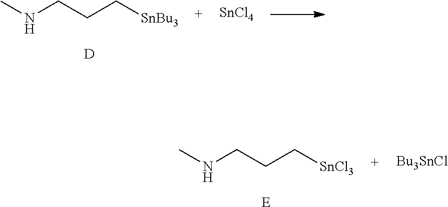

N-methyl-3-(trichlorostannyl)propan-1-amine (E) is prepared according to the scheme above as follows. Under N₂, 363.19 (1 mol) of D is charged into a 1 L flask. Tin tetrachloride is 20 added dropwise while controlling the temperature of the reaction mixture below 40° C. After addition the mixture is heated at 70° C. for an additional 4 hrs. Pure compound E is then obtained by distillation.

### Example 4 (Prophetic): Synthesis of N,N,N′,N′,1-pentamethyl-1,2-azastannolidine-2,2-diamine (G)

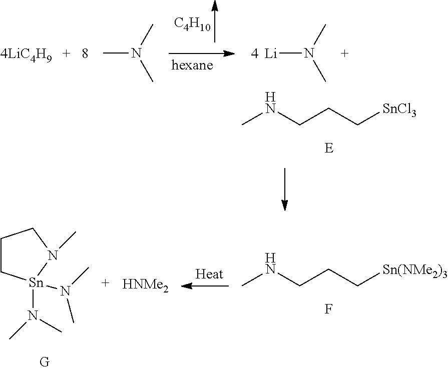

N,N,N′,N′,1-pentamethyl-1,2-azastannolidine-2,2-diamine (G) is synthesized according to the scheme above as follows. Under N2, 1500 mL of anhydrous hexanes and 839.9 g of 2.5 M n- BuLi (3.03 mol) are charged into a 5L flask. 136.6 g of dimethylamine (3.03 mol) are added subsurface at 0˜10° C. The reaction mixture is stirred for an additional four hours while warming to room temperature before 396.89 g of compound E (1 mol) premixed in 100mL toluene is added dropwise at 0˜10° C. The resulting mixture is warmed to room temperature over four hours and stirred for an additional four hours at room temperature. The reaction mixture is filtered through sparkler to remove the LiC1 byproduct. The salt is rinsed with anhydrous hexanes (2×100 mL). The solvent is removed under reduced pressure and pure compound G is obtained by distillation.

### Example 5 (Prophetic): Synthesis of N-methyl-3-(tri-tert-butoxystannyl)propan-1-amine (H)

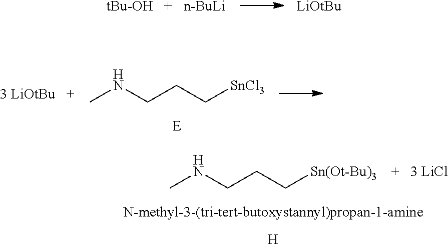

N-methyl-3-(tri-tert-butoxystannyl)propan-1-amine (H) is synthesized according to the scheme above as follows. Under N₂, 839.9 g of 2.5 M n-BuLi (3.03 mol) is charged into a 5 L flask and cooled to 0° C. 226.98 g of tertbutyl alcohol (50% in toluene, 253 g) is added subsurface at 0˜10° C. The reaction mixture is stirred for an additional four hours while warming to room temperature before 396.89 g of compound E (1 mol) premixed in 100mL toluene is added dropwise at 0-10° C. The resulting mixture is warmed to room temperature over four hours and stirred for an additional four hours at room temperature. The reaction mixture is filtered through sparkler to remove the LiCl byproduct. The salt is rinsed with anhydrous hexanes (2×100 mL). The solvent is removed under reduced pressure and pure compound H is obtained by distillation.

### Example 6 (Prophetic): Synthesis of 2,2-di-tert-butoxy-1-methyl-1,2-azastannolidine (I)

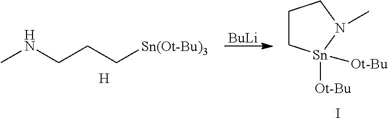

2,2-di-tert-butoxy-l-methyl-1,2-azastannolidine (I) is prepared according to the scheme above as follows. Under N₂, 410.19 g of compound H (1 mole) and 800 mL of anhydrous hexanes are charged into a 5L flask and cooled to 0° C. 277.2 g of BuLi (1 mole) is added dropwise while the temperature is maintained at 0˜10° C. After addition, the mixture is warmed to room temperature and stirred overnight. After filtration, the salt is washed twice with an additional 100 mL anhydrous hexane. Pure compound I is obtained by distillation.

### Example 7 (Prophetic): Synthesis of 2,2-dimethoxy-1,2-oxastannolane (K)

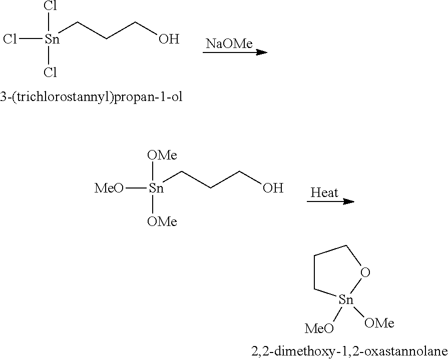 [SMILES: OCC[CH2][Sn]([Cl])([Cl])[Cl] ; C[O][Sn]([CH2]CCO)([O]C)[O]C ; "Heat" ; C[O][Sn]1([O]C)[CH2]CC[O]1 ; "NaOMe"]

3-(trichlorostannyl)propan-1-ol (J) is prepared according to the method described in Organometallics 14, 685 (1995). 2,2-dimethoxy-1,2-oxastannolane (K) is then prepared according to the scheme above as follows. Under N₂, 284.15 g of compound J (1 mole) and 500 mL of THF are charged into a 5 L flask. 648.2 g of NaOMe (25 wt % in Me0H) are added dropwise while maintaining the temperature below 50° C. The mixture is then heated at 50° C. for an additional four hours. After filtration, the salt is washed twice with an additional 100 mL of anhydrous hexane. The solvent is removed by distillation until no Me0H is observed at the distillate. Pure compound K is then obtained by distillation.

### Example 8 (Prophetic): Synthesis of N,N,N′,N′-tetramethyl-1,2-oxastannolane-2,2-diamine (L)

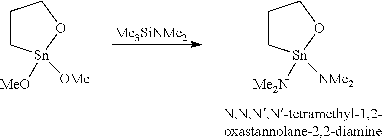 [SMILES: "Me3SiNMe2" ; C[O][Sn]1([O]C)[CH2]CC[O]1 ; C[N](C)[Sn]1([N](C)C)[CH2]CC[O]1]

Under N₂ 238.8g (1 mol) of 2,2-dimethoxy-1,2-oxastannolane (K) and 500 mL of THF are charged into a 5 L flask. 947.46 g of (dimethylamino)trimethylsilane (2.02 mole) are added dropwise and the temperature is maintained below 50° C. The mixture is then heated at about 60-70° C. while removing methoxytrimethylsilane by distillation. After no further observation of methoxytrimethylsilane, the solvent is removed under vacuum. The pure target compound is obtained by distillation.

### Example 9 (Prophetic): Purification of Inventive Compounds

The compounds prepared in Examples 1-8 are purified using fractional distillation, resulting in the target compounds having purities of at least 95 mol % and as high as greater than 99 mol %.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

We claim:

1. A cyclic azastannane having formula (I): 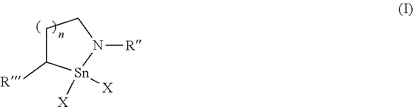
wherein X is OR or NR′₂, n is an integer of 1 to 3, R is a primary, secondary, or tertiary alkyl group having 1 to about 5 carbon atoms or a substituted or unsubstituted aryl group having about 6 to about 10 carbon atoms, R′ is a primary alkyl group having 1 to about 2 carbon atoms, R″ is hydrogen, a substituted or unsubstituted primary, secondary, or tertiary, saturated or unsaturated, linear, branched, or cyclic alkyl group having 1 to about 20 carbon atoms, a substituted or unsubstituted, branched or linear aralkyl group having about 7 to about 10 carbon atoms, or a substituted or unsubstituted aryl group having about 6 to about 10 carbon atoms, and R′″ is hydrogen, a substituted or unsubstituted primary, secondary, or tertiary, saturated or unsaturated, linear, branched, or cyclic alkyl group having 1 to about 20 carbon atoms, a substituted or unsubstituted, branched or linear aralkyl group having about 7 to about 10 carbon atoms, or a substituted or unsubstituted aryl group having about 6 to about 10 carbon atoms.

2. The cyclic azastannane according to claim 1, wherein the cyclic azastannane is N,N,N′,N′,1-pentamethyl-1,2-azastannolidine-2,2-diamine; 1-ethyl-N,N,N′,N′-tetramethyl-1,2-azastannolidine-2,2-diamine; N,N,N′,N′-tetramethyl-l-vinyl-1,2-azastannolidine-2,2-diamine, 2,2-di-tert-butoxy-l-methyl-1,2-azastannolidine; 2,2-di-tert-butoxy-l-ethyl-1,2-azastannolidine; or 2,2-di-tert-butoxy-l-vinyl-1,2-azastannolidine.

3. The cyclic azastannane according to claim 1, having a purity of at least about 90 mol %.

4. A cyclic oxostannane having formula (II): 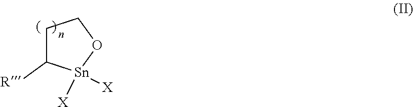
wherein X is OR or NR′₂, n is an integer of 1 to 3, R is a primary, secondary, or tertiary alkyl group having 1 to about 5 carbon atoms or a substituted or unsubstituted aryl group having about 6 to about 10 carbon atoms, R′ is a primary alkyl group having 1 to about 2 carbon atoms, and R′″ is hydrogen, a substituted or unsubstituted primary, secondary, or tertiary, saturated or unsaturated, linear, branched, or cyclic alkyl group having 1 to about 20 carbon atoms, a substituted or unsubstituted, branched or linear aralkyl group having about 7 to about 10 carbon atoms, or a substituted or unsubstituted aryl group having about 6 to about 10 carbon atoms.

5. The cyclic oxostannane according to claim 4, wherein the cyclic oxostannane is ,2- dimethoxy-1,2-oxastannolane; 2,2-di-tert-butoxy-1,2-oxastannolane; and 2,2-di-tert-butoxy-3-methyl-1,2-oxastannolane.

6. The cyclic oxostannane according to claim 4, having a purity of at least about 90 mol %.

7. A method for producing a cyclic azastannane according to claim 1 wherein X is OR, the method comprising reacting an aminoalkyltrialkoxystannane or aminoalkyltriaryloxystannane with a compound selected from the group consisting of HMDZ, an ammonium salt, sulfuric acid, a phosphonium salt, and an organolithium compound.

8. A method for producing a cyclic azastannane according to claim 1 wherein X is NR′₂, the method comprising heating an aminoalkyltrialkylaminostannane to effect cyclization.

9. A method for producing a cyclic oxostannane according to claim 4, wherein X is OR, the method comprising reacting a trichlorostannyl alcohol with a metal alkoxide to produce a trialkoxystannyl alcohol, and heating the trialkoxystannyl alcohol to effective cyclization.

10. A method for producing a cyclic oxostannane according to claim 4, wherein X is NR′₂, the method comprising reacting a (dialkylamino)trimethylsilane with a cyclic oxostannane having formula (II) wherein X is OR and R is a primary, secondary, or tertiary alkyl group having 1 to about 5 carbon atoms or a substituted or unsubstituted aryl group having about 6 to about 10 carbon atoms.
